(19) United States
(12) Patent Application Publication
(10) Pub. No.: US 2008/0301508 A1
(43) Pub. Date: Dec. 4, 2008

(54) SEMICONDUCTOR MEMORY DEFECT ANALYSIS METHOD AND DEFECT ANALYSIS SYSTEM

(76) Inventors: Mami KODAMA, Yokohama-Shi (JP); Yoshikazu Ilzuka, Kawasaki-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/126,101

(22) Filed: May 23, 2008

(30) Foreign Application Priority Data
May 31, 2007 (JP) 2007-145085

(51) Int. Cl. G11C 29/08; G06F 11/26

(52) U.S. Cl. 714/719; 714/718; 714/E11.159

(57) ABSTRACT

A defect analysis method for semiconductor memory includes: reading out an address bit map corresponding to an input kind of the memory macro from a database which stores address bit maps respectively corresponding to memory macro kinds; inputting size information of the memory macro; translating a logical address of a defective cell of the memory macro detected on the basis of results of an electric test measured by using a tester to a physical address of a memory macro in a standard disposition by using the input size information and the address bit map read out, of the memory macro, and generating a fail bit map in the standard disposition; inputting disposition information of the memory macro; and translating a physical address of the fail bit map in the standard disposition to a physical address of the memory macro by using the input disposition information of the memory macro, and generating a fail bit map of the memory macro.

### CROSS-REFERENCE TO RELATED APPLICATION

This application is based upon and claims the benefit of priority from prior Japanese Patent Application No. 2007-145085 filed on May 31, 2007 in Japan, the entire contents of which are incorporated herein by reference.

### BACKGROUND OF THE INVENTION

1. Field of the Invention

The present invention relates to a semiconductor memory defect analysis method, and defect analysis system, in which a logic address of a defective cell in a RAM (random access memory) or a ROM (read only memory) collected by a tester is translated to a physical address on a semiconductor chip having a large number of RAM macros or ROM macros mounted thereon.

2. Related Art

In a system LSI, a large number of RAM (random access memory) macros or ROM (read only memory) macros are mounted on one chip. There are a plurality of kinds (TYPEs) of these memory macros. According to the kinds, address bit maps each including information such as the number and locations of column decoders and address advance direction differ. Even if the kind of the RAM or ROM is the same, size information such as the number of IOs, the number of columns and the number of rows is defined every memory macro. In addition, there are eight kinds (N, S, E, W, FN, FS, FE and FW) in directions in which RAMs or ROMs having the same kind and size are disposed on the chip. Disposition is conducted by the designer. The present technique can be applied to memory macros which are RAM macros and/or ROM macros. In the ensuing description, however, RAM macros are taken as an example.

In the RAM macros, there is a method for identifying a defective place by using their fail bit map (FBM). For displaying the FBM, it is typical to translate a logical address (in functional design) (an address in a one-dimensional array) of a defective cell detected on the basis of results of an electric test measured by using a tester to a physical address (an address in a two-dimensional array) of a RAM macro on the wafer and display the physical address. A technique of translating logical address information of a cell judged to be defective on the basis of an electric characteristic test of the semiconductor memory to entity address array information (physical address) approximated to geometrical cell layout on a semiconductor chip by using origin information based upon the layout of the semiconductor chip which constitutes the semiconductor memory and location information for identifying a location in respective layouts of a plurality of cells as compared with the origin information and displaying a defective cell is known (see, for example, Japanese Patent No. 3256555).

In the technique described in Japanese Patent No. 3256555, however, the location information (disposition information) and size information of the RAM macro are fixed. Therefore, the technique described in Japanese Patent No. 3256555 cannot be applied to a semiconductor chip on which a large number of RAM macros which differ in kind, size and disposition are mounted.

As for creating FBM address translation equations for a large number of RAM macros individually by manual work, it takes a time and it is a difficult work to execute without knowledge of the design.

As heretofore described, it has not been easy to translate a logical address of a defective cell detected on the basis of an electric test result of a semiconductor chip having a large number of RAM macros mounted thereon, measured by using a tester to a physical address of each RAM macro on a wafer, and create and display an FBM.

### SUMMARY OF THE INVENTION

According to a first aspect of the present invention there is provided a defect analysis method for semiconductor memory including: selecting a memory macro to be analyzed from a semiconductor device having a large number of memory macros mounted on one chip, and inputting a kind of the selected memory macro; reading out an address bit map corresponding to the input kind of the memory macro from a database which stores address bit maps respectively corresponding to memory macro kinds; inputting size information of the memory macro; translating a logical address of a defective cell of the memory macro detected on the basis of results of an electric test measured by using a tester to a physical address of a memory macro in a standard disposition by using the input size information and the address bit map read out, of the memory macro, and generating a fail bit map in the standard disposition; inputting disposition information of the memory macro; and translating a physical address of the fail bit map in the standard disposition to a physical address of the memory macro by using the input disposition information of the memory macro, and generating a fail bit map of the memory macro.

According to a second aspect of the present invention there is provided a defect analysis method for semiconductor memory including: selecting a memory macro to be analyzed from a semiconductor device having a large number of memory macros mounted on one chip, and inputting an address bit map of the selected memory macro; inputting size information of the memory macro; translating a logical address of a defective cell of the memory macro detected on the basis of results of an electric test measured by using a tester to a physical address of a memory macro in a standard disposition by using the input size information and the input address bit map of the memory macro, and generating a fail bit map in the standard disposition; inputting disposition information of the memory macro; and translating a physical address of the fail bit map in the standard disposition to a physical address of the memory macro by using the input disposition information of the memory macro, and generating a fail bit map of the memory macro.

According to a third aspect of the present invention there is provided a defect analysis system for semiconductor memory including: an input unit configured to select a memory macro to be analyzed from a semiconductor device having a large number of memory macros mounted on one chip, and configured to input a kind of the selected memory macro, size information of the memory macro and disposition information of the memory macro; a readout unit configured to read out an address bit map corresponding to the input kind of the memory macro from a database which stores address bit maps respectively corresponding to memory macro kinds; a standard disposition address translation unit configured to translate a logical address of a defective cell of the memory macro detected on the basis of results of an electric test measured by using a tester to a physical address of a memory macro in a standard disposition by using the input size information and the address bit map read out, of the memory macro, and configured to generate a fail bit map in the standard disposition; and a fail bit map generation unit configured to translate a physical address of the fail bit map in the standard disposition to a physical address of the memory macro by using the input disposition information of the memory macro, and configured to generate a fail bit map of the memory macro.

According to a fourth aspect of the present invention there is provided a defect analysis system for semiconductor memory including: an input unit configured to select a memory macro to be analyzed from a semiconductor device having a large number of memory macros mounted on one chip, and configured to input an address bit map of the selected memory macro, size information of the memory macro, and disposition information of the memory macro; a standard disposition address translation unit configured to translate a logical address of a defective cell of the memory macro detected on the basis of results of an electric test measured by using a tester to a physical address of a memory macro in a standard disposition by using the input size information and the input address bit map of the memory macro, and configured to generate a fail bit map in the standard disposition; and a fail bit map generation unit configured to translate a physical address of the fail bit map in the standard disposition to a physical address of the memory macro by using the input disposition information of the memory macro, and configured to generate a fail bit map of the memory macro.

### BRIEF DESCRIPTION OF THE DRAWINGS

FIG. 1 is a flow chart showing a procedure of a defect analysis method for semiconductor memory according to a first embodiment of the present invention;

FIG. 2 is a diagram showing a defect analysis system used in the defect analysis method for semiconductor memory according to the first embodiment;

FIG. 3 is a schematic diagram showing a system LSI to which the defect analysis method according to the first embodiment is applied;

FIGS. 4A and 4B are diagrams showing examples of a RAM kind;

FIG. 5 is a diagram for explaining examples of a RAM disposition kind;

FIG. 6 is a diagram showing an example of a RAM;

FIGS. 7A and 7B are diagrams for explaining relations in physical address between a RAM in a disposition “N” and a RAM in a disposition “FS”;

FIG. 8 is a diagram showing various kinds of information of RAMs in the system LSI shown in FIG. 3;

FIG. 9 is a flow chart showing a procedure of a defect analysis method for semiconductor memory according to a second embodiment of the present invention;

FIG. 10 is a diagram showing a defect analysis system used in the defect analysis method for semiconductor memory according to the second embodiment;

FIG. 11 is a diagram showing logical addresses obtained by translation; and

FIG. 12 is a diagram showing physical addresses obtained by translation.

### DETAILED DESCRIPTION OF THE EMBODIMENT

Hereafter, embodiments of the present invention will be described in detail with reference to the drawings.

### First Embodiment

A defect analysis method for semiconductor memory according to a first embodiment of the present invention will now be described. The defect analysis method for semiconductor memory according to the present embodiment is used in a system LSI formed by mounting a large number of RAM macros on a semiconductor chip. In typical system LSIs, a microprocessing unit and a logic circuit occupy a great part of a chip layout. However, a large number of RAM macros are mounted on the chip. For example, fourteen RAM macros 2₁ to 2₁₄ are disposed dispersedly in a chip 100 as shown in FIG. 3. By the way, in FIG. 3, the RAM macros 2₁ to 2₁₄ are provided with identification codes 001 to 014, respectively.

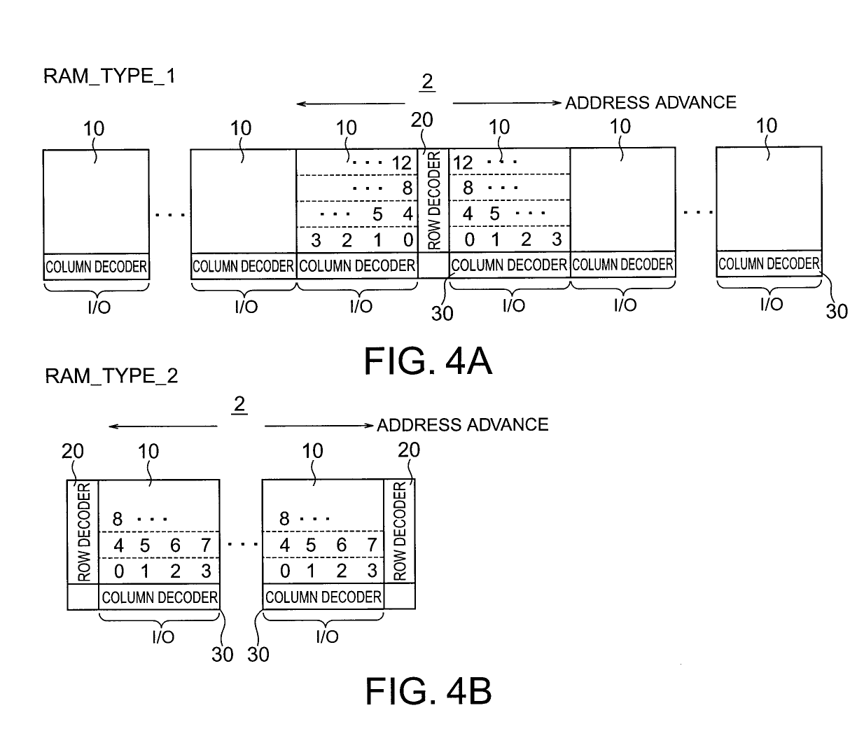

There are a plurality of kinds (TYPEs) in the RAM macros. FIGS. 4A and 4B show RAM macros of two kinds. FIG. 4A shows a RAM macro 2 denoted by, for example, RAM_TYPE1 which is one of the two kinds, and FIG. 4B shows a RAM macro 2 denoted by, for example, RAM_TYPE2 which is the other of the two kinds. RAM macros are not restricted to the two kinds, but there are more kinds of RAM macros.

As shown in FIG. 4A, the RAM macro 2 of RAM_TYPE1 includes a plurality of sub memory arrays 10, one row decoder 20, and a plurality of column decoders 30. Each sub memory array 10 includes memory cells (not illustrated) arranged in a matrix form. The sub memory arrays 10 are arranged in rows in the lateral direction and are divided into two groups. A common row decoder 20 is provided between the groups obtained by the division. A column decoder 30 is provided so as to correspond to each sub memory array. One sub memory array 10 and a column decoder 30 corresponding thereto constitute one I/O unit.

On the other hand, as shown in FIG. 4B, the RAM macro 2 of RAM_TYPE2 includes a plurality of sub memory arrays 10, two row decoders 20, and a plurality of column decoders 30. Each sub memory array 10 has memory cells (not illustrated) arranged in a matrix form. The sub memory arrays 10 are arranged in rows in the lateral direction. Row decoders 20 are provided on both sides of the sub memory arrays 10. A column decoder 30 is provided so as to correspond to each sub memory array. One sub memory array 10 and a column decoder 30 corresponding thereto constitute one I/O unit.

According to the kind of the RAM, decoder disposition and an address advance direction in a plurality of sub memory arrays are defined. For example, in the RAM macro 2 of RAM_TYPE1 shown in FIG. 4A, the address advance direction is defined so as to have a greater address as the location advances to the right in the right side sub memory array group, whereas the address advance direction is defined so as to have a greater address as the location advances to the left in the left side sub memory array group. In the RAM macro 2 of RAM_TYPE2 shown in FIG. 4B, the address advance direction is defined so as to have a greater address as the location advances from the left to the right. In this way, an address bit map including the number and disposition of row decoders and the address advance direction in the sub memory arrays is defined according to the kind (TYPE) of the RAM.

Furthermore, even if the kinds of RAMs are the same, there are RAMs which differ in size information, i.e., size and the number of sub memory arrays (the number of I/O units (the number of I/Os)). For example, in the RAM macro 2 of RAM_TYPE1 shown in FIG. 4A, the size of the sub memory arrays 10, i.e., the number of columns is four and the number of rows is four. If the number of sub memory arrays located on the left side of the row decoder is n, the number of I/Os is 2n.

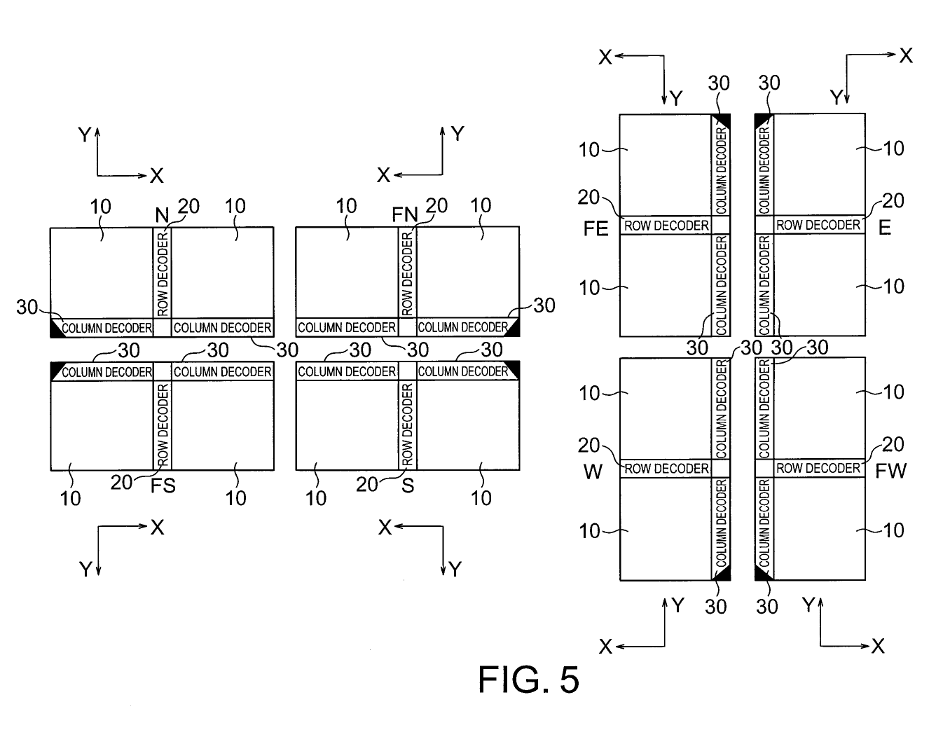

As for the RAM disposition (direction) in the chip, there are eight kinds (N, S, E, W, FN, FS, FE and FW) for each of RAM kinds (TYPES) and sizes as shown in FIG. 5, and the disposition is conducted for each of RAMs by the designer. FIG. 5 shows disposition kinds by taking a RAM macro which is a RAM of RAM_TYPE1 and 2 in the number of IOs as an example.

A RAM in the disposition “N” is taken as standard. A black triangle on the left side of a column decorder 30 located on the left side of the RAM indicates an origin mark (symbol mark) of the RAM. Coordinate systems corresponding to respective dispositions are also shown in FIG. 5. A RAM in the disposition “FN” and the RAM in the disposition “N” are in a mirror symmetry relation with respect to the Y axis. A RAM in the disposition “S” is obtained by rotating the RAM in the disposition “N” by 180 degrees in the clockwise direction or the counterclockwise direction. A RAM in the disposition “FS” and the RAM in the disposition “S” are in a mirror symmetry relation with respect to the Y axis. A RAM in the disposition “E” is obtained by rotating the RAM in the disposition “N” by 90 degrees in the clockwise direction. A RAM in the disposition “FE” and the RAM in the disposition “E” are in a mirror symmetry relation with respect to the Y axis. A RAM in the disposition “W” is obtained by rotating the RAM in the disposition “N” by 90 degrees in the counterclockwise direction. A RAM in the disposition “FW” and the RAM in the disposition “W” are in a mirror symmetry relation with respect to the Y axis.

By the way, size information and disposition information of RAMs can be extracted from circuit design information and used.

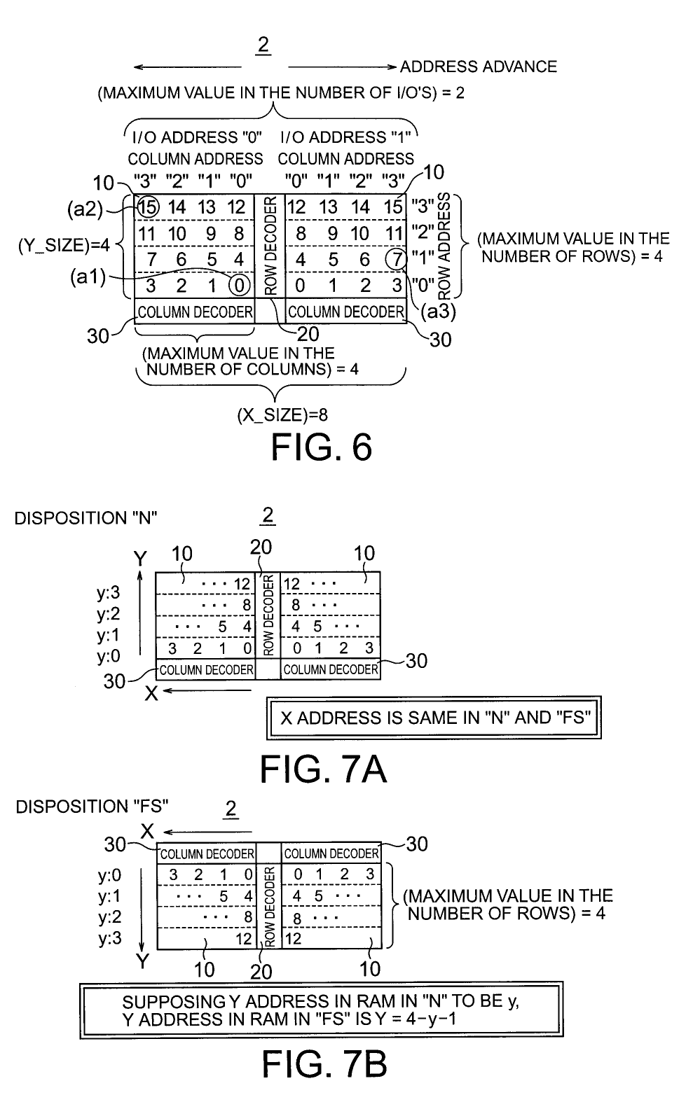

FIG. 6 shows an address bit map, i.e., decoder disposition and an address advance direction of a RAM which is “RAM_A” in RAM name, “RAM TYPE_1” in RAM TYPE, “N” in disposition, two in the number of IOs in size information, four in the number of columns, and four in the number of rows.

FIGS. 7A and 7B are diagrams showing an example of RAMs which are the same in kind and size and which are different only in disposition pattern. FIG. 7A shows a RAM in the disposition “N” which is the standard disposition, and FIG. 7B shows a RAM in the disposition “FS.” The RAM in the disposition “N” and the RAM in the disposition “FS” are the same in physical address X in the X axis direction. In other words, supposing a physical address in the X axis direction in the disposition “N” to be x, a physical address in the Y axis direction in the disposition “N” to be y, a physical address in the X axis direction in the disposition “FS” to be X, a physical address in the Y axis direction in the disposition “FS” to be Y, it follows that X=x. Supposing the maximum value in the number of rows to be Y_SIZE, however, the physical address Y in the Y axis direction of the RAM in the disposition “FS” is found by using the equation Y=Y_SIZE−y−1. In FIGS. 7A and 7B, Y_SIZE=4.

As appreciated from FIG. 5, the RAM in the disposition “N” and the RAM in the disposition “FN” are the same in physical address in the Y axis direction. In other words, supposing a physical address in the X axis direction in the disposition “N” to be x, a physical address in the Y axis direction in the disposition “N” to be y, a physical address in the X axis direction in the disposition “FN” to be X, a physical address in the Y axis direction in the disposition “FN” to be Y, it follows that Y=y. Supposing the total number of columns (=the number of columns in each sub memory array×the number of IOs) to be X_SIZE, however, the physical address X in the X axis direction of the RAM in the disposition “FN” is found by using an equation X=X_SIZE−x−1.

As for physical addresses in the RAM in the disposition “N” and in the RAM in the disposition “S”, it is appreciated from FIG. 5 that a physical address X in the X axis direction of the RAM in the disposition “S” is found by using an equation X=X_SIZE−x−1, where x is the physical address in the X axis direction in the disposition “N”. A physical address Y in the Y axis direction of the RAM in the disposition “S” is found by using an equation Y=Y_SIZE−y−1, where y is the physical address in the Y axis direction in the disposition “N”.

As for physical addresses in the RAM in the disposition “N” and in the RAM in the disposition “E”, it is appreciated from FIG. 5 that a physical address X in the X axis direction of the RAM in the disposition “E” is found by using an equation X=y, where y is the physical address in the Y axis direction in the disposition “N”. A physical address Y in the Y axis direction of the RAM in the disposition “E” is found by using an equation Y=x, where x is the physical address in the X axis direction in the disposition “N”.

As for physical addresses in the RAM in the disposition “N” and in the RAM in the disposition “FE”, it is appreciated from FIG. 5 that a physical address X in the X axis direction of the RAM in the disposition “FE” is found by using an equation X=Y_SIZE−y−1, where y is the physical address in the Y axis direction in the disposition “N”. A physical address Y in the Y axis direction of the RAM in the disposition “FE” is found by using an equation Y=x, where x is the physical address in the X axis direction in the disposition “N”.

As for physical addresses in the RAM in the disposition “N” and in the RAM in the disposition “W”, it is appreciated from FIG. 5 that a physical address X in the X axis direction of the RAM in the disposition “E” is found by using an equation X=Y_SIZE−y, where y is the physical address in the Y axis direction in the disposition “N”. A physical address Y in the Y axis direction of the RAM in the disposition “W” is found by using an equation Y=X_SIZE−x−1, where x is the physical address in the X axis direction in the disposition “N”.

As for physical addresses in the RAM in the disposition “N” and in the RAM in the disposition “FW”, it is appreciated from FIG. 5 that a physical address X in the X axis direction of the RAM in the disposition “FW” is found by using an equation X=y, where y is the physical address in the Y axis direction in the disposition “N”. A physical address Y in the Y axis direction of the RAM in the disposition “FW” is found by using an equation Y=X_SIZE−x−1, where x is the physical address in the X axis direction in the disposition “N”.

As heretofore described, physical addresses in a RAM in a different disposition are found from the physical addresses in the RAM in the standard disposition “N.”

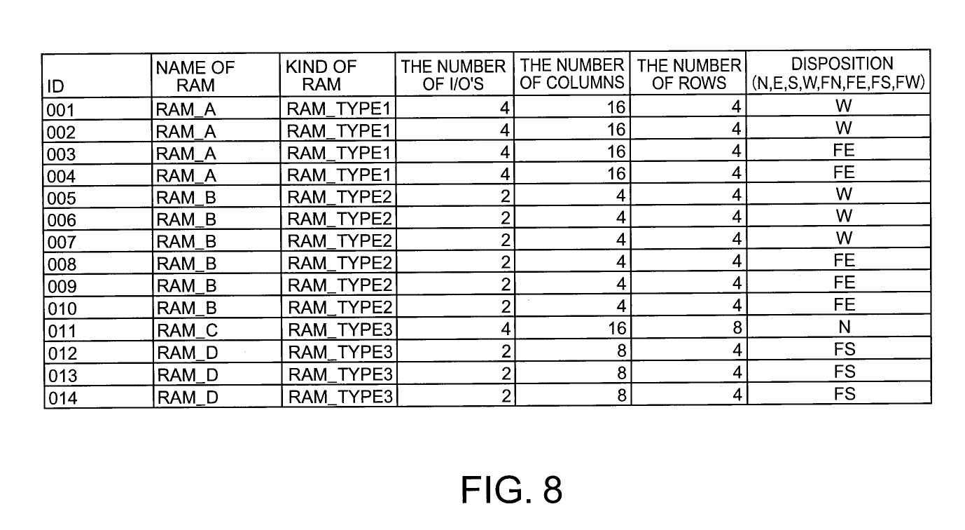

FIG. 8 shows an example of identification codes, RAM names, RAM kinds, size information (the number of IOs, the number of columns, and the number of rows), and disposition information of the fourteen RAM macros 2₁ to 2₁₄ shown in FIG. 3.

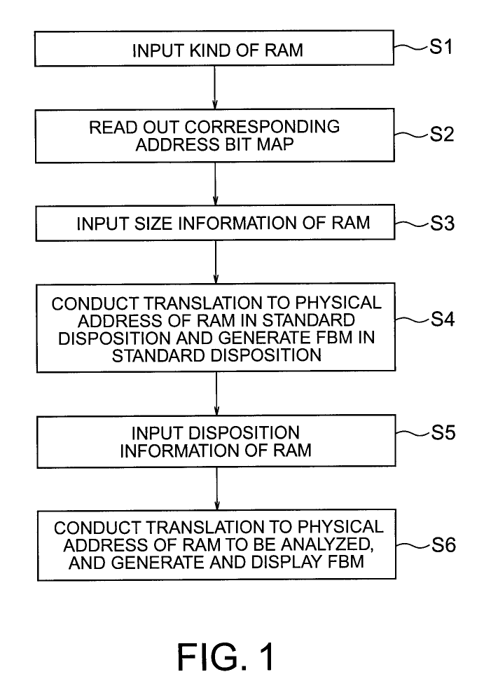

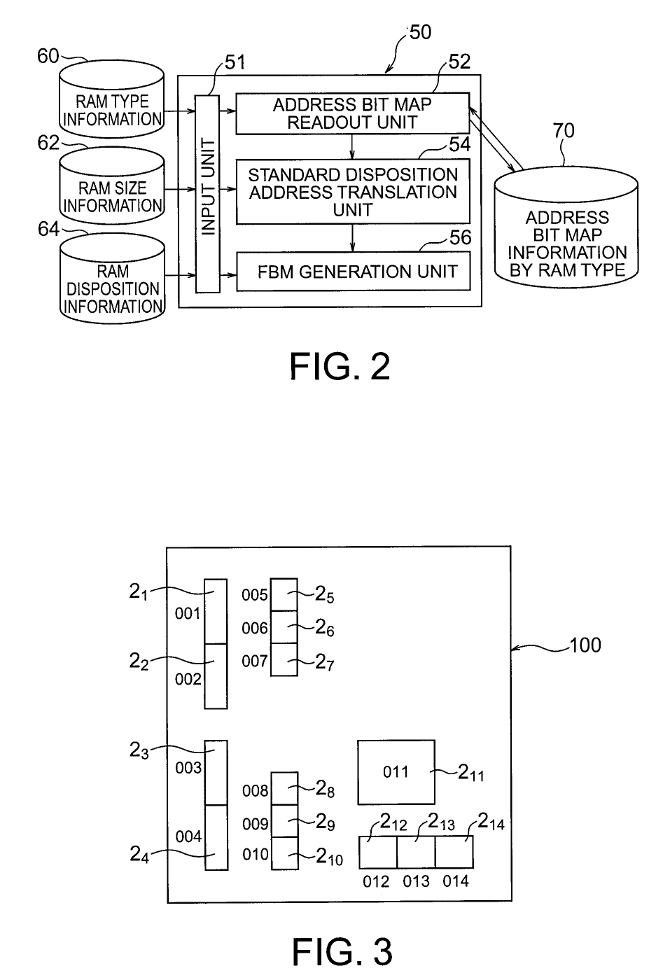

A defect analysis method for semiconductor memory according to the present embodiment will now be described. A procedure of the defect analysis method for semiconductor memory according to the present embodiment is shown in FIG. 1. A defect analysis system for semiconductor memory used in the defect analysis method for semiconductor memory according to the present embodiment is shown in FIG. 2. A defect analysis system 50 includes an input unit 51, an address bit map readout unit 52, a standard disposition address translation unit 54, and an FBM generation unit 56. The defect analysis method according to the present embodiment is executed as described hereafter.

First, a RAM to be analyzed is selected from a system LSI having a large number of RAM macros mounted thereon. A database 60 which stores kinds (TYPEs) of RAMs is referenced, and a kind of the RAM to be analyzed is input to the input unit 51 (step S1 in FIG. 1). For example, the kind RAM_TYPE1 of the RAM2₁ shown in FIG. 3 is input to the input unit 51. Thereupon, the address bit map readout unit 52 reads out an address bit map corresponding to the input RAM kind from a database 70 which stores an address bit map for each RAM kind (step S2 in FIG. 1).

Subsequently, a database 62 which stores RAM sizes is referenced, and size information of the RAM is input to the input unit 51 (step S3 in FIG. 1). For example, the size of the RAM shown in FIG. 6, i.e., the number of IOs which is 2, the number of columns which is 4, and the number of rows which is 4 are input to the input unit 51. Thereupon, a logical address of a defective cell detected on the basis of results of an electric test measured by using a tester is translated to a physical address concerning the RAM in the standard disposition “N” by the standard disposition address translation unit 54 on the basis of the size information of the RAM and the address bit map, and an FBM (fail bit map) in the standard disposition is generated (step S4 in FIG. 1).

The address translation in the standard disposition is a well-known technique. In system LSIs, however, sizes defined by the number of I/Os, the number of columns, and the number of rows are often different even if the RAM kind is the same and the address bit map information (i.e., the decoder disposition and address advance direction in the memory array) is the same. The present invention has a feature different from the conventional art in that it is made possible to easily generate address translation equations of RAMs which are different in size if the RAMs are those of the same RAM kind (in other words, of the same address bit map) by extracting address bit map information and size information as parameters in the address translation of the standard disposition. For example, operation is conducted as hereafter described.

First, size information of the RAM shown in FIG. 6 is as follows:

maximum number of I/Os=2; maximum number of columns=4; maximum number of rows=4; X_SIZE=(maximum number of IOs “2”)×(maximum number of columns “4”)=2×4=8, and Y_SIZE=(maximum number of rows “4”)=4.

As for the I/O address, the I/O address of a sub memory located on the left side of the row decoder is denoted by “0,” and the I/O address of a sub memory located on the right side of the row decoder is denoted by “1.” Row addresses 0 to 3 are assigned to rows in order from a bottom row located nearest the column decoder upward. Column address assignment is conducted every sub memory. In a sub memory located on the left side of the row decoder, column addresses 0 to 3 are assigned in order from the right to the left. In a sub memory located on the right side of the row decoder, column addresses 0 to 3 are assigned in order from the left to the right.

An example of equations serving as templates for address translation used to find a standard disposition physical address and a logical address of an address bit map for the RAM kind shown in FIG. 6 by using the maximum number of I/Os, the maximum number of columns, the maximum number of rows, the maximum size in the column direction (X_SIZE)=(maximum number of I/Os)×(maximum number of columns), and the maximum size in the row direction (Y_SIZE)=(maximum number of rows) as parameters will now be described. The following two equations are obtained according to whether the I/O address at the pertinent point is less than or at least (the maximum number of I/Os÷2). Address translation equations of each RAM is generated by substituting size information into these template equations.

In the case where [(I/O address)<(maximum number of I/Os)÷2] (1)

(Standard disposition X physical address)=(the maximum number of columns)×(I/O address+1)−1−(column address)

(Standard disposition Y physical address)=(the maximum number of rows)−(row address)−1

(Logical address)=(X_SIZE)×(Standard disposition Y physical address)+(Standard disposition X physical address)

In the case where [(I/O address)≧(maximum number of I/Os)÷2] (2)

(Standard disposition X physical address)=(the maximum number of columns)×(I/O address)+(column address)

(Standard disposition Y physical address)=(the maximum number of rows)−(row address)−1

(Logical address)=(X_SIZE)×(Standard disposition Y physical address)+(Standard disposition X physical address)

(i) In FIG. 6, (a1) is a point where I/O address=0, row address=0 and column address=0, and the translation equations are applied to (a1).

First, since (I/O address “0”)<(maximum number of I/Os “2”)÷2, Equation (1) is used.

(Standard disposition X physical address)=(the maximum number of columns “4”)×(I/O address “0”+1)−1−(column address “0”)=4×1−1−0=3

(Standard disposition Y physical address)=(the maximum number of rows “4”)−(row address “0”)−1=4−0−1=3

(Logical address)=(X_SIZE)×(Standard disposition Y physical address)+(Standard disposition X physical address)=(X_SIZE “8”)×(Standard disposition Y physical address “3”)+(Standard disposition X physical address “3”)=27

At (a1) in FIG. 6, therefore, the physical address (X, Y)=(3, 3) and the logical address becomes 27.

(ii) In FIG. 6, (a2) is a point where I/O address=0, row address=3 and column address=3, and the translation equations are applied to (a2).

First, since (I/O address “0”)<(maximum number of I/Os “2”)÷2, Equation (1) is used.

(Standard disposition X physical address)=(the maximum number of columns “4”)×(I/O address “0”+1)−1−(column address “3”)=4×1−1−3=0

(Standard disposition Y physical address)=(the maximum number of rows “4”)−(row address “3”)−1=4−3−1=0

(Logical address)=(X_SIZE)×(Standard disposition Y physical address)+(Standard disposition X physical address)=(X_SIZE “8”)×(Standard disposition Y physical address “0”)+(Standard disposition X physical address “0”)=8×0+0=0

At (a2) in FIG. 6, therefore, the physical address (X, Y)=(0, 0) and the logical address becomes 0.

(iii) In FIG. 6, (a3) is a point where I/O address=1, row address=1 and column address=3, and the translation equations are applied to (a3).

First, since (I/O address “1”)≧(maximum number of I/Os “2”)÷2, Equation (2) is used.

(Standard disposition X physical address)=(the maximum number of columns “4”)×(I/O address “1”)+(column address “3”)=4×1+3=7

(Standard disposition Y physical address)=(the maximum number of rows “4”)−(row address “1”)−1=4−1−1=2

(Logical address)=(X_SIZE “8”)×(Standard disposition Y physical address “2”)+(Standard disposition X physical address “7”)=8×2+7=23

At (a3) in FIG. 6, therefore, the physical address (X, Y)=(7, 2) and the logical address becomes 23.

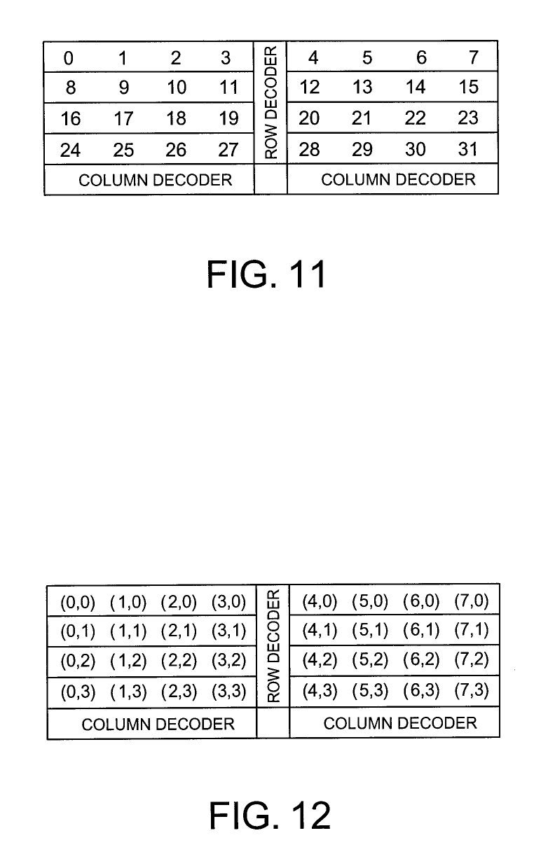

All addresses are translated according to the description of (i) to (iii). As a result, logical addresses shown in FIG. 11 are obtained. In the uppermost row of the RAM, the logical address becomes 0 to 7 in order as the column advances from the left to the right. In the second uppermost row of the RAM, the logical address becomes 8 to 15 in order as the column advances from the left to the right. In the bottom row (the fourth uppermost row), the logical address at the rightmost column becomes 31.

And the physical addresses obtained by the translation become as shown in FIG. 12. At the leftmost column in the uppermost row of the RAM, the physical address becomes (0, 0). The X address increases from 0 to 7 as the location advances from the left to the right. The Y address increases from 0 to 3 as the location advances from the top to the bottom. In the bottom row (the fourth uppermost row), the physical address at the rightmost column becomes (7, 3).

With respect to FIG. 4A which is the same in RAM kind (in other words, address bit map) and which is different in the number of I/Os as well, the logical address and the physical address can be found in the same way by using the number of I/Os, the number of columns and the number rows as parameters and using the equations. By associating the logical address and the physical address with each other, it becomes possible to translate the logical address detected by the tester to a physical address and display the FBM in the standard disposition. Address translation templates such as the Equations (1) and (2) are prepared previously and incorporated every address bit map. The FBM display is just the same as the physical addresses. The top left of the RAM is the origin (0, 0). In the X direction, there are eight bits 0 to 7 from the left to the right. In the Y address, there are four bits 0 to 3 in order from the top to the bottom. Thus, the FBM display has a lattice form of 8×4=32 bits. A logical address of a defect detected on the basis of results of an electric test measured by using a tester is translated to a physical address. Thereafter, the physical address is displayed as a defective cell by coloring or the like in order to distinguish from normal cells.

FIG. 8 is a table obtained by putting together parameters which are input when generating FBM address translation equations by using the present embodiment for fourteen macros in the system LSI shown in FIG. 3. ID is a serial number for each of fourteen macros. If the RAM names are the same, then the RAM kinds and size information (the number of I/Os, the number of columns, and the number of rows) are also the same. Dispositions might be different because they are subjected to layout separately by the designer. Even if RAM kinds are the same, size information (the number of I/Os, the number of columns, and the number of rows) might be different, and dispositions might be different because they are subjected to layout separately by the designer.

The macros 001 (2₁) to 004 (2₄) are “RAM_A” in RAM name, “RAM_TYPE1” in RAM kind, four in the number of I/Os, sixteen in the number of columns, and four in the number of rows. Thus, the macros 001 (2₁) to 004 (2₄) are the same in all of the RAM name, RAM kind, and size. However, it is indicated that they are different in disposition, i.e., the macros 001 (2₁) and 002 (2₂) are “W” in disposition whereas the macros 003 (2₃) and 004 (2₄) are “FE” in disposition. All of 011 (2₁₁) to 014 (2₁₄) are the same “RAM_TYPE3” in RAM kind. However, 011 (2₁₁) is, as regards the size, four in the number of I/Os, sixteen in the number of columns, and eight in the number of rows, and “RAM_C” in RAM name. On the other hand, 012 (2₁₂) to 014 (2₁₄) are, as regards the size, two in the number of I/Os, eight in the number of columns, and four in the number of rows, and “RAM_D” in RAM name.

Subsequently, a database 64 which stores RAM disposition information is referenced, and disposition information of the RAM is input to the input unit 51 (step S5 in FIG. 1). For example, the disposition information of the RAM 2₁ shown in FIG. 3, i.e., the disposition “W” is input to the input unit 51. Thereupon, a physical address of the RAM FBM is found by the FBM generation unit 56 on the basis of the disposition information of the RAM and a physical address concerning the RAM in the standard disposition “N.” An FBM represented by the physical address is generated and displayed on, for example, a display device which is not illustrated (step S6 in FIG. 1).

In the present embodiment, the RAM kind (TYPE), RAM size and RAM disposition information are input successively. Alternatively, the information may be input at first.

Even if a large number of RAM macros are mounted on a semiconductor chip, the present embodiment makes it possible to easily generate an FBM by only inputting a kind, size information and disposition information of a RAM macro as heretofore described.

### Second Embodiment

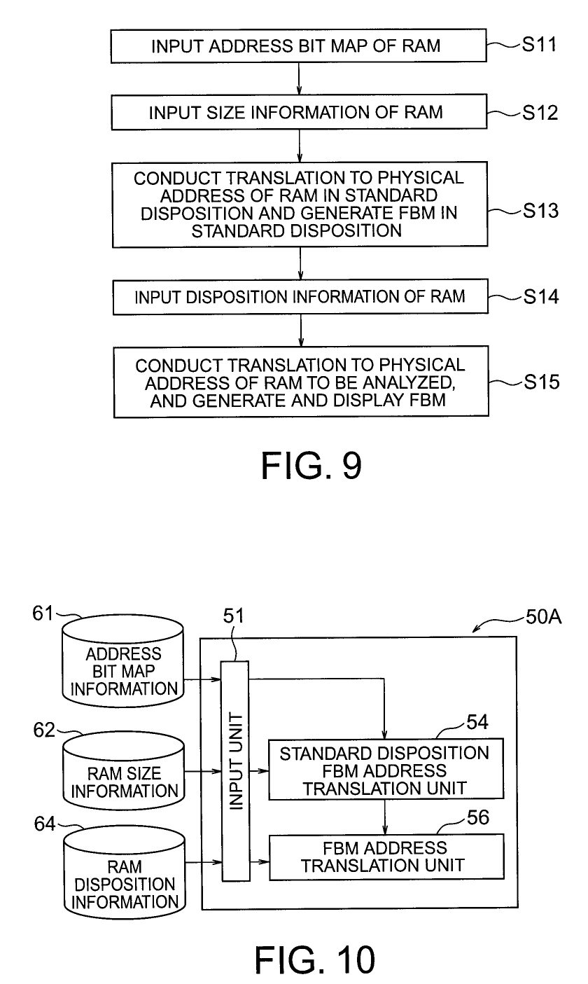

A defect analysis method for semiconductor memory according to a second embodiment of the present invention will now be described. A procedure of the defect analysis method for semiconductor memory according to the present embodiment is shown in FIG. 9. A defect analysis system for semiconductor memory used in the defect analysis method for semiconductor memory according to the present embodiment is shown in FIG. 10. A defect analysis system 50A includes an input unit 51, a standard disposition FBM address translation unit 54, and an FBM address translation unit 56. The defect analysis method according to the present embodiment is executed as described hereafter.

First, a RAM to be analyzed is selected from a system LSI having a large number of RAM macros mounted thereon. A database 61 which stores address bit map information is referenced, and an address bit map of the RAM to be analyzed is input to the input unit 51 (step S11 in FIG. 9).

Subsequently, a database which stores RAM sizes is referenced, and size information of the RAM is input to the input unit 51 (step S12 in FIG. 9). Thereupon, a logical address of a defective cell detected on the basis of results of an electric test measured by using a tester is translated to a physical address concerning the RAM in the standard disposition “N” by the standard disposition address translation unit 54 on the basis of the size information of the RAM and the address bit map in the same way as the first embodiment, and an FBM in the standard disposition is generated (step S13 in FIG. 9). The address translation in the standard disposition is the well-known technique. However, the present embodiment has a feature different from the conventional art in that it is made possible to easily generate address translation equations of RAMs which are different in size by extracting address bit map information and size information as parameters if address translation template equations such as the Equations (1) and (2) are previously incorporated into address bit maps.

Subsequently, a database 64 which stores RAM disposition information is referenced, and disposition information of the RAM is input to the input unit 51 (step S14 in FIG. 9). Thereupon, a physical address of the RAM FBM is found by the FBM generation unit 56 on the basis of the disposition information of the RAM and a physical address concerning the RAM in the standard disposition “N.” An FBM represented by the physical address is generated and displayed on, for example, a display device which is not illustrated (step S15 in FIG. 9).

In the present embodiment, the address bit map information of the RAM, RAM size and RAM disposition information are input successively. Alternatively, the information may be input at first.

According to the present invention, an FBM can be generated easily by only inputting the address bit map information, size information and disposition information of the RAM as heretofore described.

According to the embodiments of the present invention, translation of a logical address of a defective cell on a semiconductor chip having a large number of memory macros mounted thereon to a physical address in each memory macro on the wafer can be conducted easily.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A defect analysis method for semiconductor memory comprising:
selecting a memory macro to be analyzed from a semiconductor device having a large number of memory macros mounted on one chip, and inputting a kind of the selected memory macro;
reading out an address bit map corresponding to the input kind of the memory macro from a database which stores address bit maps respectively corresponding to memory macro kinds;
inputting size information of the memory macro;
translating a logical address of a defective cell of the memory macro detected on the basis of results of an electric test measured by using a tester to a physical address of a memory macro in a standard disposition by using the input size information and the address bit map read out, of the memory macro, and generating a fail bit map in the standard disposition;
inputting disposition information of the memory macro; and
translating a physical address of the fail bit map in the standard disposition to a physical address of the memory macro by using the input disposition information of the memory macro, and generating a fail bit map of the memory macro.

2. The defect analysis method for semiconductor memory according to claim 1, wherein
the memory macro comprises a column decoder, a row decoder and an I/O unit,
the address bit map comprises number of column decoders in the memory macro, locations of the column decoders, and an address advance direction in the memory macro, and
the size information comprises number of I/O units in the memory macro, number of columns in the memory macro, and number of rows in the memory macro.

3. The defect analysis method for semiconductor memory according to claim 1, wherein the generating of a fail bit map in the standard disposition comprises:
comparing an address of an I/O unit to which a subject memory cell in the memory macro belongs with half a value equivalent to a maximum value in the number of the I/O units; and
finding a standard disposition X physical address, a standard disposition Y physical address, and a logical address in the memory macro in the standard disposition, corresponding to the memory cell according to following equations,
if the address of the I/O unit<the maximum value in the number of I/O units÷2,
(standard disposition X physical address)=(a maximum value in the number of columns in the memory macro)×(the address of the I/O unit+1)−1−(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address),
if the address of the I/O unit≧the maximum value in the number of I/O units÷2,
(standard disposition X physical address)=(a maximum value in the number of columns in the memory macro)×(the address of the I/O unit)+(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address).

4. A defect analysis method for semiconductor memory comprising:
selecting a memory macro to be analyzed from a semiconductor device having a large number of memory macros mounted on one chip, and inputting an address bit map of the selected memory macro;
inputting size information of the memory macro;
translating a logical address of a defective cell of the memory macro detected on the basis of results of an electric test measured by using a tester to a physical address of a memory macro in a standard disposition by using the input size information and the input address bit map of the memory macro, and generating a fail bit map in the standard disposition;
inputting disposition information of the memory macro; and
translating a physical address of the fail bit map in the standard disposition to a physical address of the memory macro by using the input disposition information of the memory macro, and generating a fail bit map of the memory macro.

5. The defect analysis method for semiconductor memory according to claim 4, wherein
the memory macro comprises a column decoder, a row decoder and an I/O unit,
the address bit map comprises number of column decoders in the memory macro, locations of the column decoders, and an address advance direction in the memory macro, and
the size information comprises number of I/O units in the memory macro, number of columns in the memory macro, and number of rows in the memory macro.

6. The defect analysis method for semiconductor memory according to claim 4, wherein the generating of a fail bit map in the standard disposition comprises:
comparing an address of an I/O unit to which a subject memory cell in the memory macro belongs with half a value equivalent to a maximum value in the number of the I/O units; and
finding a standard disposition X physical address, a standard disposition Y physical address, and a logical address in the memory macro in the standard disposition, corresponding to the memory cell according to following equations,
if the address of the I/O unit<the maximum value in the number of I/O units÷2,
(standard disposition X physical address)=(a maximum value in the number of columns in the memory macro)×(the address of the I/O unit+1)−1−(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address),
if the address of the I/O unit≧the maximum value in the number of I/O units÷2,
(standard disposition X physical address)=(a maximum value in the number of columns in the memory macro)×(the address of the I/O unit)+(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address).

7. A defect analysis system for semiconductor memory comprising:
an input unit configured to select a memory macro to be analyzed from a semiconductor device having a large number of memory macros mounted on one chip, and configured to input a kind of the selected memory macro, size information of the memory macro and disposition information of the memory macro;
a readout unit configured to read out an address bit map corresponding to the input kind of the memory macro from a database which stores address bit maps respectively corresponding to memory macro kinds;
a standard disposition address translation unit configured to translate a logical address of a defective cell of the memory macro detected on the basis of results of an electric test measured by using a tester to a physical address of a memory macro in a standard disposition by using the input size information and the address bit map read out, of the memory macro, and configured to generate a fail bit map in the standard disposition; and
a fail bit map generation unit configured to translate a physical address of the fail bit map in the standard disposition to a physical address of the memory macro by using the input disposition information of the memory macro, and configured to generate a fail bit map of the memory macro.

8. The defect analysis system for semiconductor memory according to claim 7, wherein
the memory macro comprises a column decoder, a row decoder and an I/O unit,
the address bit map comprises number of column decoders in the memory macro, locations of the column decoders, and an address advance direction in the memory macro, and
the size information comprises number of I/O units in the memory macro, number of columns in the memory macro, and number of rows in the memory macro.

9. The defect analysis system for semiconductor memory according to claim 7, wherein the standard disposition address translation unit compares an address of an I/O unit to which a subject memory cell in the memory macro belongs with half a value equivalent to a maximum value in the number of the I/O units, and finds a standard disposition X physical address, a standard disposition Y physical address, and a logical address in the memory macro in the standard disposition, corresponding to the memory cell according to following equations,
if the address of the I/O unit<the maximum value in the number of I/O units÷2,
(standard disposition X physical address)=(a maximum value in the number of columns in the memory macro)×(the address of the I/O unit+1)−1−(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address),
if the address of the I/O unit≧the maximum value in the number of I/O units÷2,
(standard disposition X physical address)=(a maximum value in the number of columns in the memory macro)×(the address of the I/O unit)+(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address).

10. A defect analysis system for semiconductor memory comprising:
an input unit configured to select a memory macro to be analyzed from a semiconductor device having a large number of memory macros mounted on one chip, and configured to input an address bit map of the selected memory macro, size information of the memory macro, and disposition information of the memory macro;
a standard disposition address translation unit configured to translate a logical address of a defective cell of the memory macro detected on the basis of results of an electric test measured by using a tester to a physical address of a memory macro in a standard disposition by using the input size information and the input address bit map of the memory macro, and configured to generate a fail bit map in the standard disposition; and
a fail bit map generation unit configured to translate a physical address of the fail bit map in the standard disposition to a physical address of the memory macro by using the input disposition information of the memory macro, and configured to generate a fail bit map of the memory macro.

11. The defect analysis system for semiconductor memory according to claim 10, wherein
the memory macro comprises a column decoder, a row decoder and an I/O unit,
the address bit map comprises number of column decoders in the memory macro, locations of the column decoders, and an address advance direction in the memory macro, and
the size information comprises number of I/O units in the memory macro, number of columns in the memory macro, and number of rows in the memory macro.

12. The defect analysis system for semiconductor memory according to claim 10, wherein the standard disposition address translation unit compares an address of an I/O unit to which a subject memory cell in the memory macro belongs with half a value equivalent to a maximum value in the number of the I/O units; and finds a standard disposition X physical address, a standard disposition Y physical address, and a logical address in the memory macro in the standard disposition, corresponding to the memory cell according to following equations,
if the address of the I/O unit<the maximum value in the number of I/O units÷2,
(standard disposition X physical address)=(a maximum value in the number of columns in the memory macro)×(the address of the I/O unit+1)−1−(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address),
if the address of the I/O unit≧the maximum value in the number of I/O units÷2,
(standard disposition X physical address)=(a maximum value in the number of columns in the memory macro)×(the address of the I/O unit)+(a column address of the memory cell),
(standard disposition Y physical address)=(a maximum value in the number of rows in the memory macro)−(a row address of the memory cell)−1, and
(logical address)=(the maximum value in the number of the I/O units×maximum value of the column)×(the standard disposition Y physical address)+(the standard disposition X physical address).
